(19) United States
(12) Patent Application Publication
(10) Pub. No.: US 2009/0267142 A1
(43) Pub. Date: Oct. 29, 2009

(54) SEMICONDUCTOR DEVICE AND METHOD OF MANUFACTURING SAME

(75) Inventor: Kinya OTANI, KANAGAWA (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/428,686

(22) Filed: Apr. 23, 2009

(30) Foreign Application Priority Data
Apr. 23, 2008 (JP) 2008-112487

(51) Int. Cl. H01L 29/78; H01L 21/28

(52) U.S. Cl. 257/330; 438/586; 257/E29.262; 257/E21.158

(57) ABSTRACT

A semiconductor device according to the present invention includes a plurality of trenches, a plurality of gate electrodes, a plurality of diffusion Layers, an insulating film, an electrode layer, a plurality of first concave portions and a plurality second concave portions formed in the electrode layer, a solder layer, and an electrically conducting board. The gate electrode is located in each of the plurality of trenches. The plurality of diffusion layers is adjacent to the respective trenches. The insulating films are selectively formed on the respective gate electrodes. The first concave portions are located above spaces between the gate electrodes. The second concave portions are located between the first concave portions. The electrically conducting board is connected to the electrode layer through the solder layers.

This application is based on Japanese patent application No. 2008-112,487, the content of which is incorporated hereinto by reference.

### BACKGROUND

1. Technical Field

The present invention relates to a semiconductor device having a trench gate transistor and a method of manufacturing thereof.

2. Related Art

FIG. 6 is a cross-sectional view, illustrating an example of a semiconductor device employed as a power device. A semiconductor device illustrated here includes a trench gate transistor. Diffusion layers 206 and 207 and trenches 205 are formed in the semiconductor substrate 200, and the inside of the trench 205 is provided with a gate insulating film 212 and a gate electrode 202. An insulating film 203 is formed on the gate electrode 202. An electrode layer 210 is formed over the insulating film 203 and over the diffusion layer 207. Concave portions 208 resulted from existences of the insulating films 203 are formed in the surface of the electrode layer 210.

The electrode layer 210 is coupled to an electrically conducting board 213 through solder layers 211. The solder layers 211 are provided in regions in the surface of the electrode layer 210 except the concave portions 208. A semiconductor device employed as power device is described in Japanese Patent Laid-Open No. 2003-101,024.

However, the present inventor has found the following problem. When the electrically conducting board is coupled to the electrode layer via a solder layer, such solder layer is heated to a temperature that is not lower than the melting point thereof. Then, the solder layer is naturally cooled to a room temperature, so that the solder is hardened to provide a coupling the electrode layer with the electrically conducting board. In such case, a difference in the thermal expansion coefficient between the electrode layer and the solder layer may causes cracks (portions indicating by 214 in FIG. 5) in the electrode layer. Such cracks as a starting point may expand to create damages in portions of the connection between the diffusion layer and the electrode layer or in a gate insulating film, possibly causing failure in characteristics such as a leakage and the like.

### SUMMARY

According to one aspect of the present invention, there is provided a semiconductor device, comprising: a plurality of trenches formed in a semiconductor substrate; a gate electrode located in each of the plurality of trenches; a plurality of diffusion layers, formed in the semiconductor substrate and being adjacent to the plurality of trenches, respectively; an insulating film selectively formed over each of the plurality of gate electrodes; an electrode layer formed continually over the plurality of diffusion layers and over -the insulating films; a plurality of first concave portions, formed in the electrode layer and located above spaces between each of the plurality of gate electrodes; second concave portions, formed in the electrode layer and located between each of the plurality of first concave portions; a solder layer provided on the surface of the electrode layer; and an electrically conducting board coupled to the electrode layer through the solder layer.

According to another aspect of the present invention, there is provided a method of manufacturing a semiconductor device, including: forming a plurality of trench gate transistors in a semiconductor substrate; forming an electrode layer and a plurality of first concave portions, the electrode layer being located above the plurality of transistors and being coupled to a plurality of diffusion layers included in the respective transistors, the first concave portion being located above spaces between each of the plurality of gate electrodes of the transistors; forming a plurality of second concave portions in the the electrode layer by selectively removing the electrode layer; providing a solder layer over regions in the surface of the electrode layer except the first and second concave portions; and coupling the electrode layer with an electrically conducting board via the solder layer.

According to the present invention, stress per single one of the first and the second concave portions is reduced, thereby inhibiting stress concentration on specific portions in the electrode layer to create cracks. This results in an improved reliability of the semiconductor device.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view of a semiconductor device according to an embodiment;

FIG. 2 is a cross-sectional view, useful in describing the method of manufacturing the semiconductor device shown in FIG. 1;

FIG. 3 is a cross-sectional view to useful in describing the operation carried out subsequent to the process shown in FIG. 2;

FIG. 4 is a cross-sectional view to useful in describing the operation carried out subsequent to the process shown in FIG. 3;

FIG. 5 is a cross-sectional view, illustrating an example of a semiconductor device employed as a power device which has an above mentioned problem of cracks; and

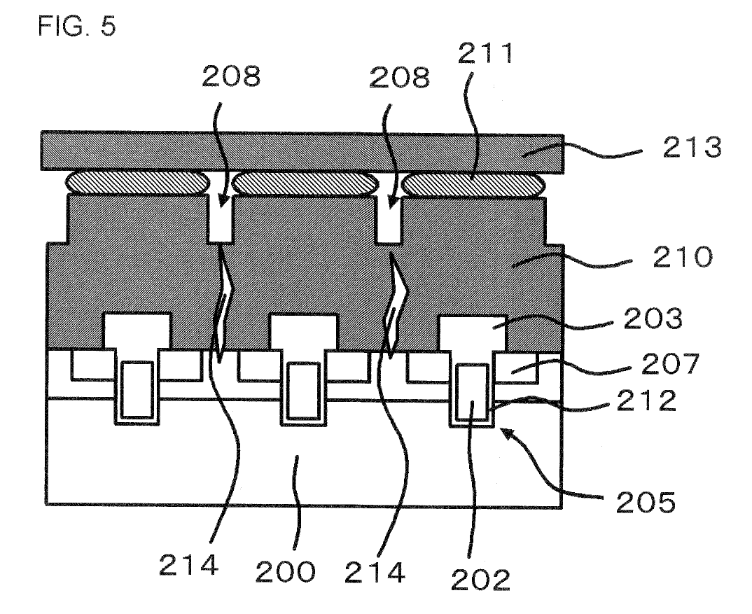

FIG. 6 is a cross-sectional view, illustrating a semiconductor device of prior art.

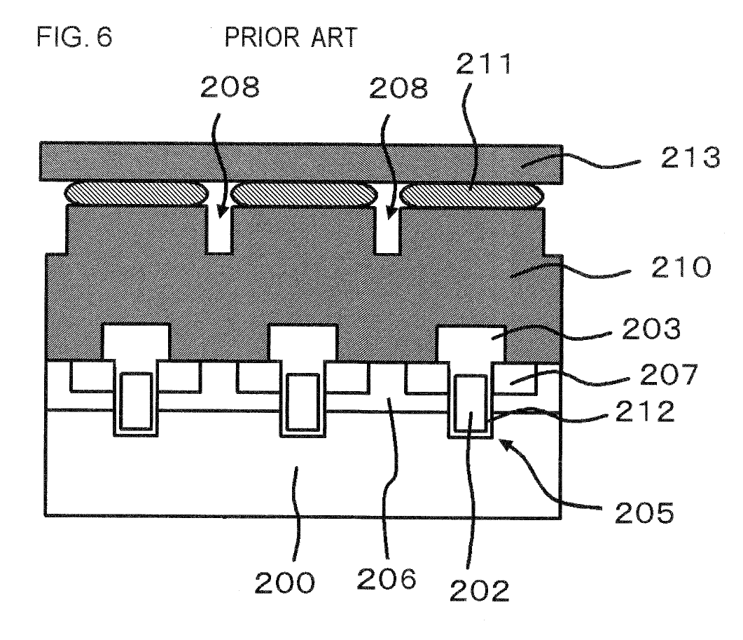

### DETAILED DESCRIPTION

The invention will now be described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in detail as follows in reference to the annexed figures. In all figures, an identical numeral is assigned to an element commonly appeared in the figures, and the detailed description thereof will not be repeated.

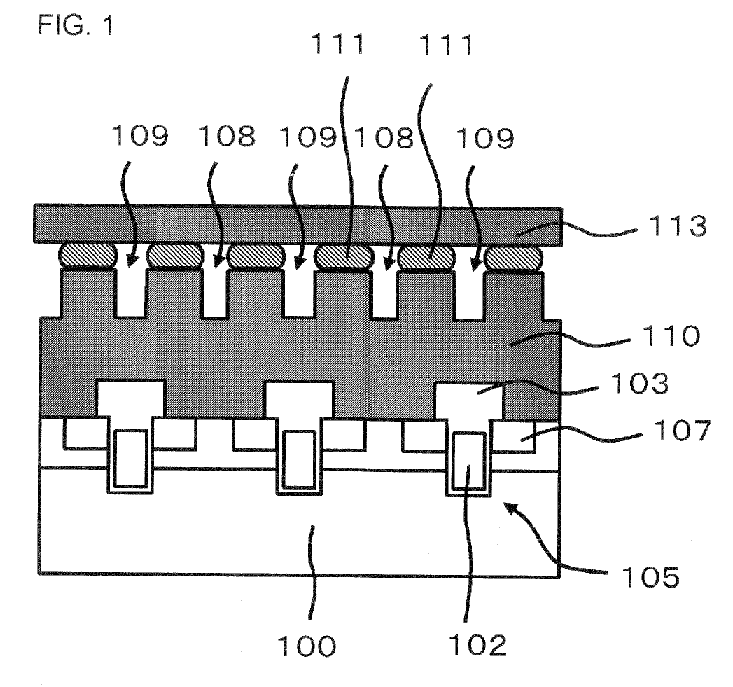

FIG. 1 is a cross-sectional view of a semiconductor device according to an embodiment. The semiconductor device is a power device having a plurality of trench gate transistors, and includes plurality of trenches 105, plurality of gate electrodes 102, plurality of diffusion layers 107, an insulating film 103, an electrode layer 110, plurality of concave portions 108 and 109 formed in the electrode layer 110, a solder layer 111, and an electrically conducting board 113.

The trench 105 is formed in the semiconductor substrate 100 of silicon substrate. The gate electrode 102 is located in each of plurality of trenches 105. A plurality of diffusion layers 107 are adjacent to the respective trenches 105. The diffusion layer 107 has a first conductivity type (n type, for example), and functions as a source of the transistor. The insulating films 103 are selectively formed on the respective gate electrodes 102.

The electrode layers 110 are the source electrodes of the transistor, and are continually formed above the diffusion layers 107 and above the insulating films 103. The concave portions 108 are located above spaces between the gate electrodes 102, and are created as the results of the existences of the insulating films 103. The concave portions 109 are located between the concave portions 108. While the embodiment illustrated in FIG. 1 represents that a single concave portion 109 is formed in a single space between the concave portions 108, plurality of concave portions 109 may be formed in the single space. The solder layers 111 are provided on the surfaces of the electrode layer 110. The electrically conducting board 113 is connected to the electrode layer 110 through the solder layers 111. The depths of the concave portions 108 and 109 may be preferably equal to or smaller than a half of the distance from the surface of the electrode layer 110 to the surface of the insulating film 103. The depth of the concave portion 109 is within a range of from 50% to 150% of the depth of the concave portion 108. The concave portions 108 and 109 preferably have the equivalent depth.

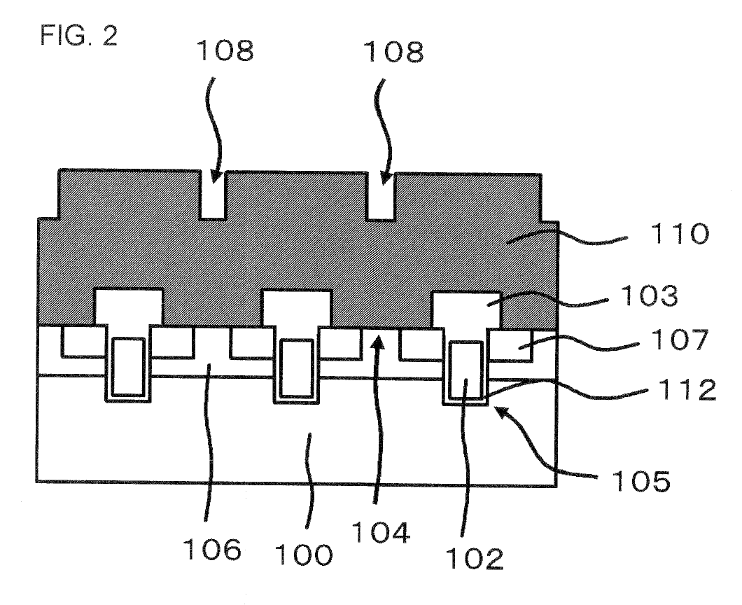

FIG. 2 to FIG. 4 are cross-sectional views, useful in describing a method of manufacturing the semiconductor device shown in FIG. 1. First of all, as shown in FIG. 2, a trench gate transistor is formed in a semiconductor substrate. Such transistor includes gate electrodes 102 and diffusion layers 107, and in addition, a gate insulating film 112 and diffusion layer 106. The gate insulating film 112 is located in an inner wall of the trench 105. The diffusion layer 106 has a second conductivity type (p type, for example), and is located under the diffusion layer 107. The diffusion layer 106 functions as a base of the transistor.

Subsequently, the insulating films 103 are formed. The insulating films 103 are formed by forming a film via, for example, a chemical vapor deposition process, and then the formed film is selectively removed to provide the insulating films selectively above the gate electrodes 102.

Subsequently, the electrode layer 110 is formed. The electrode layer 110 is, for example, an aluminum (Al) electrode layer, and formed via, for example, a sputter process. The electrode layer 110 is physically and electrically isolated from the gate electrodes 102 by the presence of the insulating films 103. At this time, the concave portions 108 resulted from the existences of the insulating films 103 are formed in the surface of the electrode layer 110. The concave portions 108 are located above contact regions 104, which are located in spaces between the gate electrodes 102. In the contact region 104, the electrode layer 110 is connected to the diffusion layer 107. In addition to above, in the embodiment illustrated in FIG. 2, the diffusion layers 107 of a plurality of transistors are coupled to the electrode layer 110 in a single contact region 104.

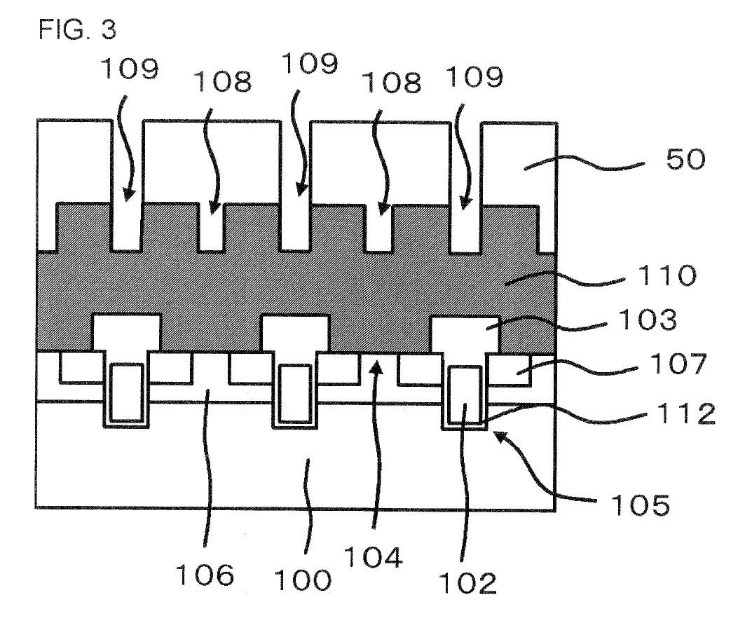

Subsequently, as shown in FIG. 3, a patterned mask 50 is formed on the electrode layer 110. The patterned mask 50 may be a patterned resist, or may be a hard mask. Subsequently, the electrode layer 110 is etched through a mask of the patterned mask 50. This process allows forming the concave portions 109.

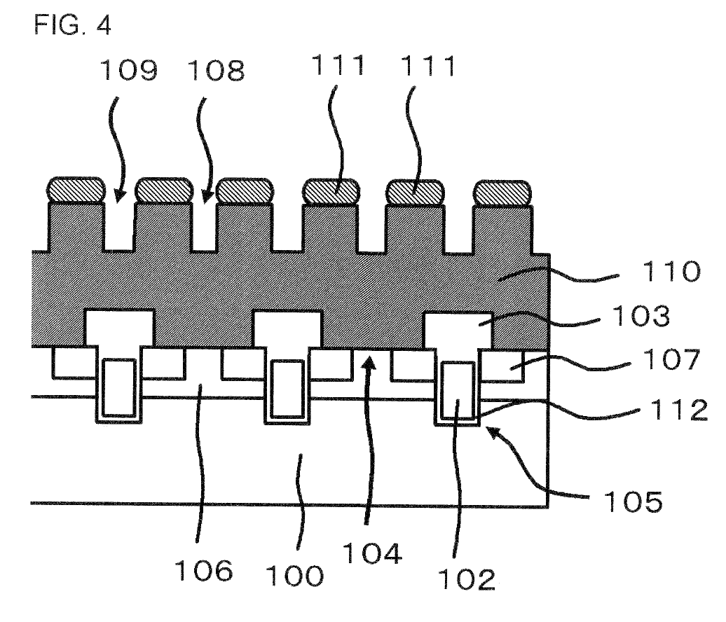

Subsequently, as shown in FIG. 4, the patterned mask 50 is removed. Subsequently, a solder layer 111 is formed by a coating process application in surface of electrode layer 110. At this time, the solder layer 111 is not formed in the concave portions 108 and 109. In addition to above, a thermal expansion coefficient of the solder layer 111 is larger than a thermal expansion coefficient of the electrode layer 110.

Thereafter, the electrically conducting board 113 shown in FIG. 1 is disposed on the solder layer 111, and a reflow soldering of solder layer 111 is carried out. This allows coupling the electrode layer 110 with the electrically conducting board 113 via the solder layers 111. In this way, the semiconductor device shown in FIG. 1 is formed.

Next, advantageous effects of the embodiment as described above will be described. In electrode layer 110, a plurality of concave portions are 109 are also formed, in addition to a plurality of concave portions 108 created as the results of the existences of the insulating films 103. Consequently, a thermal stress generated between the solder layer 111 and the electrode layer 110 when the solder layer 111 is hardened is dispersed by the presence of the concave portions 108 and 109. This advantageous effect is more enhanced as the quantity of the concave portions 109 is increased. Therefore, a stress per single one of the concave portions 108 and 109 is reduced, thereby inhibiting stress concentration on specific portions in the electrode layer to create cracks. This results in an improved reliability of the semiconductor device. This effect is more considerable when the depth of the concave portion 109 is within a range of from 50% to 150% of the depth of the concave portion 108, and particularly considerable the depth of the concave portion 108 is equivalent to the depth of the concave portion 109. Further, when the depths of the concave portions 108 and 109 are within a range of from ⅕ to ½ of the distance from the surface of the electrode layer 110 to the surface of the insulating film 103, a balancing of a force for dividing the thermal stress with a strength degradation of the electrode layer 110 due to the presence of the concave portions 108 and 109, so that the above-described advantageous effect is considerable.

While the preferred embodiments of the present invention have been described above in reference to the annexed figures, it should be understood that the disclosures above are presented for the purpose of illustrating the present invention and various modifications other than that described above are also available.

It is apparent that the present invention is not limited to the above embodiment, and may be modified and changed without departing from the scope and spirit of the invention.

What is claimed is:

1. A semiconductor device, comprising:
a plurality of trenches formed in a semiconductor substrate;
a gate electrode located in each of said plurality of trenches;
a plurality of diffusion layers, formed in said semiconductor substrate and being adjacent to said plurality of trenches, respectively;
an insulating film selectively formed over each of said plurality of gate electrodes;
an electrode layer formed continually over said plurality of diffusion layers and over said insulating films;
a plurality of first concave portions, formed in said electrode layer and located above spaces between each of said plurality of gate electrodes;
second concave portions, formed in said electrode layer and located between each of said plurality of first concave portions;
a solder layer provided on the surface of said electrode layer; and
an electrically conducting board coupled to said electrode layer through said solder layer.

2. The semiconductor device as set forth in claim 1, wherein a depth of said second concave portion is within a range of from 50% to 150% of a depth of said first concave portion.

3. The semiconductor device as set forth in claim 2, wherein the depth of said first concave portion is substantially equivalent to the depth of said second concave portion.

4. The semiconductor device as set forth in claim 1,
wherein the depth of said first concave portion and the depth of said second concave portion are within a range of from ⅕ to ½ of a distance from a surface of said electrode layer to a surface of said insulating film.

5. A method of manufacturing a semiconductor device, comprising:
forming a plurality of trench gate transistors in a semiconductor substrate;
forming an electrode layer and a plurality of first concave portions, said electrode layer being located above said plurality of transistors and being coupled to a plurality of diffusion layers included in said respective transistors, said first concave portion being located above spaces between each of said plurality of gate electrodes of said transistors;
forming a plurality of second concave portions in the said electrode layer by selectively removing said electrode layer;
providing a solder layer over regions in the surface of said electrode layer except said first and second concave portions; and
coupling said electrode layer with an electrically conducting board via said solder layer.
